(19) United States
(12) Patent Application Publication
(10) Pub. No.: US 2016/0133831 A1
(43) Pub. Date: May 12, 2016

(54) METHOD OF FORMING METAL OXIDE LAYER AND MAGNETIC MEMORY DEVICE INCLUDING THE SAME

(71) Applicants: Ki Woong KIM, Hwaseong-si (KR); Yongsung PARK, Suwon-si (KR); Yunjae LEE, Seoul (KR); Joonmyoung LEE, Anyang-si (KR); Woo Chang LIM, Seongnam-si (KR)

(72) Inventors: Ki Woong KIM, Hwaseong-si (KR); Yongsung PARK, Suwon-si (KR); Yunjae LEE, Seoul (KR); Joonmyoung LEE, Anyang-si (KR); Woo Chang LIM, Seongnam-si (KR)

(21) Appl. No.: 14/919,718

(22) Filed: Oct. 21, 2015

(30) Foreign Application Priority Data
Nov. 10, 2014 (KR) 10-2014-0155548

(51) Int. Cl. H01L 43/12; C23C 14/58; C23C 14/16; C23C 14/18; C23C 14/34; C23C 14/08

(52) U.S. Cl. CPC H01L 43/12; C23C 14/34; C23C 14/081; C23C 14/082; C23C 14/083; C23C 14/08; C23C 14/165; C23C 14/185; C23C 14/5853; H01L 43/08

(57) ABSTRACT

A method of forming a metal oxide layer and a magnetic memory device includes a post-oxidation process in which a process cycle is performed at least once, which includes depositing a metal layer on a magnetic layer and oxidizing the metal layer.

### CROSS-REFERENCE TO RELATED APPLICATIONS

This U.S. non-provisional patent application claims priority under 35 U.S.C. §119 to Korean Patent Application No. 10-2014-0155548, filed on Nov. 10, 2014, in the Korean Intellectual Property Office, the entire contents of which are hereby incorporated by reference.

### BACKGROUND OF THE INVENTION

Example embodiments disclosed herein relate to a semiconductor device, and in particular, to a magnetic memory device and a method of fabricating the same.

Due to the increased demand for electronic devices with a fast speed and/or a low power consumption, a semiconductor device requires a fast operating speed and/or a low operating voltage. A magnetic memory device has been suggested to satisfy such requirements. For example, a magnetic memory device can provide technical advantages, such as low latency and non-volatility. As a result, a magnetic memory device is being regarded as an emerging next-generation memory device.

A magnetic memory device may include a magnetic tunnel junction (MTJ). An MTJ may include two magnetic layers and a tunnel barrier layer interposed therebetween. Resistance of an MTJ may vary depending on magnetization directions of the magnetic layers. For example, the resistance of an MTJ may be higher when magnetization directions of the magnetic layers are anti-parallel than when the magnetization directions are parallel. Such a difference in resistance can be used to store data in a magnetic memory device. However, more research is still needed to mass-produce a magnetic memory device.

### SUMMARY

Embodiments disclosed herein provide a layer-forming method capable of reducing a resistance-area product (RA) value of a tunnel barrier layer in a perpendicular magnetization memory device with interface perpendicular magnetic anisotropic magnetic tunnel junctions.

Other example embodiments disclosed herein provide an interface perpendicular magnetic anisotropic magnetic memory device including magnetic tunnel junctions having a higher tunnel magnetoresistance (TMR) ratio and a uniformly lower RA value.

According to example embodiments disclosed herein, a method is provided to form an interface perpendicular magnetic anisotropic (IPMA) magnetic tunnel junction including a magnetic layer and a tunnel insulating layer. In the method, the tunnel insulating layer may be formed by sequentially performing a post-oxidation process and a stabilizing process. The post-oxidation process may include performing at least once a process cycle including depositing a metal layer on the magnetic layer and oxidizing the metal layer.

In example embodiments, the depositing of the metal layer may include a DC sputtering process using a DC power.

In example embodiments, the post-oxidation process may include repeating the process cycle several times, and the post-oxidation process may be performed in such a way that an output level of the DC power in the DC sputtering process increases with the number of repetition of the process cycle.

In example embodiments, the post-oxidation process may include repeating the process cycle several times, and the post-oxidation process may be performed in such a way that a deposition thickness of the metal layer increases with the number of repetition of the process cycle.

In example embodiments, the post-oxidation process may include repeating the process cycle several times, and the post-oxidation process may be performed in such a way that an output level of the DC power in the DC sputtering process and a deposition thickness of the metal layer increase with the number of repetition of the process cycle.

In example embodiments, the DC sputtering process may be performed using at least one of tantalum, magnesium, ruthenium, iridium, platinum, palladium, titanium, aluminum, magnesium zinc, hafnium, or magnesium boron as a sputtering target material and using at least one of argon or krypton as a sputtering source material.

In example embodiments, the DC sputtering process may be performed using a DC power ranging from about 20 W to about 100 W.

In example embodiments, the post-oxidation process may include repeating the process cycle several times, and the post-oxidation process may be performed in such a way that the metal layer formed in the first process cycle may have an effective deposition thickness ranging from about 0.1 to about 1.5 Ångströms.

In example embodiments, the oxidizing of the metal layer may include supplying oxygen-containing gas on the metal layer at a flow rate of about 0.1 to about 200 sccm at a temperature of about 15° C. to about 50° C. for a supply time of about 0.5 to about 10 seconds.

In example embodiments, the post-oxidation process may include repeating the process cycle several times, the oxidizing of the metal layer may include supplying oxygen-containing gas on the metal layer, and the post-oxidation process may be performed in such a way that a flow rate of the oxygen-containing gas increases with the number of repetition of the process cycle.

In example embodiments, the post-oxidation process may include repeating the process cycle several times, the oxidizing of the metal layer may include supplying oxygen-containing gas on the metal layer, and the post-oxidation process may be performed in such a way that a supply time of the oxygen-containing gas increases with the number of repetition of the process cycle.

In example embodiments, the post-oxidation process may include repeating the process cycle several times, the oxidizing of the metal layer may include supplying oxygen-containing gas on the metal layer, and the post-oxidation process may be performed in such a way that a flow rate and a supply time of the oxygen-containing gas increase with the number of repetition of the process cycle.

In example embodiments, forming of the tunnel insulating layer may further include performing at least once a pre-oxidation process of depositing a metal oxide on a resulting structure to which the post-oxidation process has been performed.

In example embodiments, the pre-oxidation process may be performed using an RF sputtering process. Here, in the RF sputtering process, at least one of tantalum oxide, magnesium oxide, ruthenium oxide, iridium oxide, platinum oxide, palladium oxide, titanium oxide, aluminum oxide, magnesium zinc oxide, hafnium oxide, or magnesium boron oxide may be used as a sputtering target material.

In example embodiments, the pre-oxidation process may be performed in such a way that the metal oxide has a thickness of about 3 Ångströms to about 10 Ångströms.

In example embodiments, the stabilizing process may include a low-temperature annealing step performed at a temperature of about 50° C. to about 200° C. for about 10 seconds to about 1000 seconds.

According to example embodiments disclosed herein, a magnetic memory device may be configured to include the IPMA tunnel junction fabricated by the above method.

According to example embodiments disclosed herein, a magnetic memory device may include a plurality of magnetic tunnel junctions. Here, each of the magnetic tunnel junctions may include a pair of magnetic layers and a tunnel insulating layer interposed therebetween and may have a TMR ratio ranging from about 150% to about 200%. The tunnel insulating layer may have an RA value ranging from about 5 Ohm/μm² to about 22 Ohm/μm² and may have a body centered cubic (BCC) lattice structure, allowing one of the magnetic layers disposed thereunder to have an interface perpendicular magnetic anisotropy.

In example embodiments, in the magnetic memory device, a standard deviation in RA values of the magnetic tunnel junctions may range from about 5% to about 10%.

In example embodiments, the tunnel insulating layer may be formed of tantalum oxide, magnesium oxide, ruthenium oxide, iridium oxide, platinum oxide, palladium oxide, titanium oxide, aluminum oxide, magnesium zinc oxide, hafnium oxide, or magnesium boron oxide, and one of the magnetic layers in contact with a bottom surface of the tunnel insulating layer may be formed of one of ferromagnetic materials.

An example embodiment provides a method of forming an interface perpendicular magnetic anisotropic (IPMA) magnetic tunnel junction, comprising: forming a tunnel insulating layer on a magnetic layer by performing a post-oxidation process at least one time, the post-oxidation process comprising depositing a metal layer and oxidizing the deposited metal layer, a first time the post-oxidation process is performed, a first metal layer is deposited on the magnetic layer, and subsequent times the post-oxidation process is performed, the metal layer is deposited on an oxidized metal layer. In example embodiments, the tunnel insulating layer comprises a body centered cubic lattice structure. In example embodiments, the post-oxidation process is performed a predetermined number of times in which the predetermined number of times is three times. In example embodiments, the IPMA tunnel junction comprises part of a magnetic memory device.

In example embodiments, the method further comprise low-temperature annealing the tunnel insulating layer in which the low-temperature annealing is performed at a temperature of about 50° C. to about 200° C. for about 10 seconds to about 1000 seconds.

In example embodiments, a deposition thickness of each metal layer increases with the number of repetition of the post-oxidation process. In example embodiments, a process time of each post-oxidation process decreases with the number of repetition of the post-oxidation process.

In example embodiments, depositing the metal layer comprises a DC sputtering process using a DC power, and an output level of the DC power during the DC sputtering process increases with the number of repetition of the post-oxidation process. In other example embodiments, an output level of the DC power during the DC sputtering process and a deposition thickness of each metal layer increase with the number of repetition of the post-oxidation process.

In example embodiments, depositing the metal layer comprises a DC sputtering process using a DC power, and an output level of the DC power during a second DC sputtering process is greater than an output level during a first DC sputtering process, and an output level of the DC power during a third DC sputtering process is substantially the same as the DC power during the second DC sputtering process, the third DC sputtering process being subsequent to the second DC sputtering process and the second DC sputtering process being subsequent to the first DC sputtering process.

In example embodiments, depositing the metal layer comprises a DC sputtering process using at least one of tantalum, magnesium, ruthenium, iridium, platinum, palladium, titanium, aluminum, magnesium zinc, hafnium, or magnesium boron as a sputtering target material and using at least one of argon or krypton as a sputtering source.

In example embodiments, depositing the metal layer comprises a DC sputtering process using a DC power level ranging from about 20 W to about 100 W.

In example embodiments, the metal layer deposited in a first post-oxidation process comprises an effective deposition thickness ranging from about 0.1 Ångströms to about 1.5 Ångströms.

In example embodiments, oxidizing a deposited metal layer comprises supplying oxygen-containing gas on the metal layer at a flow rate of about 0.1 sccm to about 200 sccm at a temperature of about 15° C. to about 50° C. for a supply time of about 0.5 seconds to about 10 seconds.

In example embodiments, oxidizing a deposited metal layer comprises supplying oxygen-containing gas on the metal layer in which a flow rate of the oxygen-containing gas increases with the number of repetition of the post-oxidation process. In other example embodiments, oxidizing a deposited metal layer comprises supplying oxygen-containing gas on the metal layer in which a supply time of the oxygen-containing gas increases with the number of repetition of the post-oxidation process. In yet other example embodiments, oxidizing a deposited metal layer comprises supplying oxygen-containing gas on the metal layer in which a flow rate and a supply time of the oxygen-containing gas increase with the number of repetition of the post-oxidizing process.

In example embodiments, forming the tunnel insulating layer further comprises performing at least once a pre-oxidation process of depositing a metal oxide on an oxidized deposited metal layer. In example embodiments, the pre-oxidation process is performed using an RF sputtering process in which at least one of tantalum oxide, magnesium oxide, ruthenium oxide, iridium oxide, platinum oxide, palladium oxide, titanium oxide, aluminum oxide, magnesium zinc oxide, hafnium oxide, or magnesium boron oxide is used as a sputtering target material.

In example, embodiments, the metal oxide deposited during the pre-oxidation process comprises a thickness of about 3 Ångströms to about 10 Ångströms.

An example embodiment provides a magnetic memory element, comprising a magnetic tunnel junction in which the magnetic tunnel junction comprises a first magnetic layer, a second magnetic layer, and a tunnel insulating layer between the first and second magnetic layers. The tunnel insulating layer comprises a crystallized metal oxide layer, and at least one of the first and the second magnetic layers comprises an interface perpendicular magnetic anisotropy.

In example embodiments, the tunnel insulating layer further comprises a body center cubic (BCC) lattice structure, a tunnel magnetoresistance (TMR) ratio ranging from about 150% to about 200%, and a resistance-area product (RA) value ranging from about 5 Ohm/μm² to about 22 Ohm/μm².

In example embodiments, the magnetic memory element is one of a plurality of magnetic memory elements of a magnetic memory device, and a standard deviation in RA values of the magnetic memory elements range from about 5% to about 10%.

In example embodiments, the tunnel insulating layer comprises tantalum oxide, magnesium oxide, ruthenium oxide, iridium oxide, platinum oxide, palladium oxide, titanium oxide, aluminum oxide, magnesium zinc oxide, hafnium oxide, or magnesium boron oxide, and one of the first or the second magnetic layers in contact with a bottom surface of the tunnel insulating layer is comprises formed of a ferromagnetic material.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a block diagram illustrating a magnetic memory device according to exemplary embodiments disclosed herein.

FIG. 2 is a circuit diagram of a memory cell array of a magnetic memory device according to exemplary embodiments disclosed herein.

FIG. 3 is a diagram exemplarily illustrating a magnetic tunnel junction (MTJ) memory element ME according to exemplary embodiments disclosed herein.

FIG. 4 is a plan view provided to illustrate a method of fabricating a memory device according to exemplary embodiments disclosed herein.

FIGS. 5 through 8 are sectional views illustrating a method of fabricating a memory device according to exemplary embodiments disclosed herein.

FIG. 9 is a flow chart illustrating a method of forming a metal oxide according to exemplary embodiments disclosed herein.

FIG. 10 is a flow chart illustrating an example of the method of forming a metal oxide according to exemplary embodiments disclosed herein.

FIGS. 11 through 15 are graphs illustrating some aspects of the method of forming a metal oxide according to exemplary embodiments disclosed herein.

FIG. 16 is transmission electron microscope (TEM) image showing diffraction pattern obtained from metal oxides according to experimental example.

FIG. 17 is transmission electron microscope (TEM) image showing diffraction pattern obtained from metal oxides according to comparative example.

FIG. 18 is a graph showing TMR properties of magnetic tunnel junctions according to the experimental and comparative examples.

FIG. 19 is a graph showing RA properties of the magnetic tunnel junctions according to the experimental and comparative examples.

FIG. 20 is a graph showing standard deviations in RA values of the magnetic tunnel junctions according to the experimental and comparative examples.

FIG. 21 is a schematic block diagram illustrating an example of electronic systems including a semiconductor memory device according to example embodiments disclosed herein.

FIG. 22 is a schematic block diagram illustrating an example of memory cards including a semiconductor memory device according to example embodiments disclosed herein.

FIG. 23 is a schematic block diagram illustrating an example of information processing systems including a magnetic memory device according to example embodiments disclosed herein.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments will now be described more fully with reference to the accompanying drawings, in which example embodiments are shown. Example embodiments disclosed herein may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, the element can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first,” “second,” etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments disclosed herein should not be construed as limited to the particular shapes of regions illustrated herein, but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

In an embodiment disclosed herein, a three dimensional (3D) memory array is provided. The 3D memory array is monolithically formed in one or more physical levels of arrays of memory cells having an active area disposed above a silicon substrate and circuitry associated with the operation of those memory cells, whether such associated circuitry is above or within such substrate. The term “monolithic” means that layers of each level of the array are directly deposited on the layers of each underlying level of the array.

Unless otherwise defined, all terms (including technical and scientific terms) used herein have the same meaning as commonly understood by one of ordinary skill in the art to which example embodiments disclosed herein belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

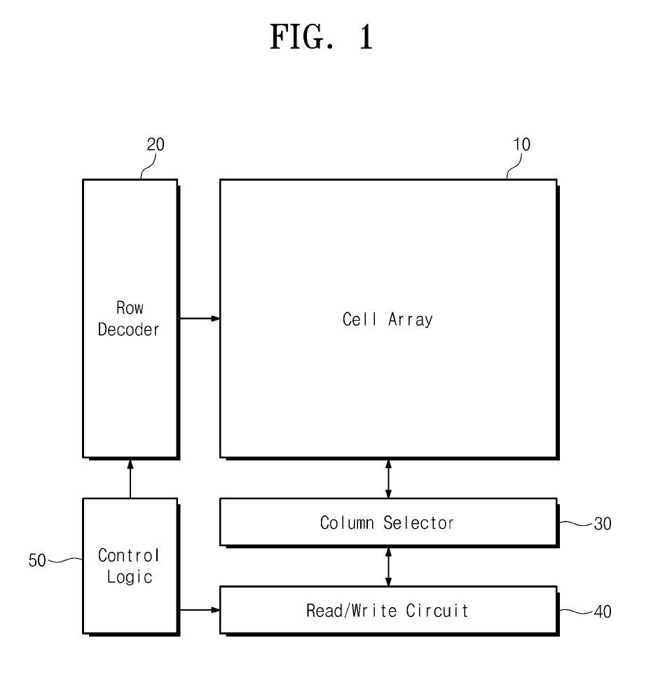

FIG. 1 is a block diagram illustrating a magnetic memory device according to exemplary embodiments disclosed herein.

Referring to FIG. 1, a magnetic memory device may include a memory cell array 10, a row decoder 20, a column selection circuit 30, a read/write circuit 40, and a control logic 50.

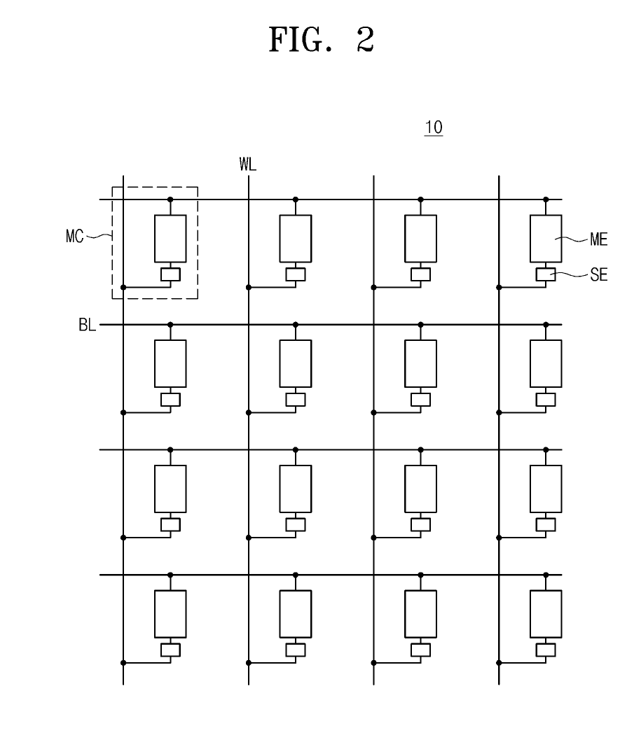

The memory cell array 10 may include plurality of word lines, a plurality of bit lines, and a plurality of memory cells. The memory cells may be provided at respective intersections of the word and bit lines and may be accessed or controlled through the word and bit lines. Configuration of the memory cell array 10 will be described in more detail with reference to FIG. 2.

The row decoder 20 may be connected to the memory cell array 10 through the word lines. The row decoder 20 may be configured to select at least one of the word lines based on address information input from the outside.

The column selection circuit 30 may be connected to the memory cell array 10 through the bit lines. The column selection circuit 30 may be configured to select at least one of the bit lines based on address information input from the outside. The at least one of the bit lines selected by the column selection circuit 30 may be connected to the read/write circuit 40.

The read/write circuit 40 may be configured to perform an operation of reading or writing data from or to the selected ones of the memory cells in response to control of the control logic 50.

The control logic 50 may output control signals for controlling the magnetic memory device according to command signals provided from the outside. The read/write circuit 40 may be controlled by the control signals output from the control logic 50.

FIG. 2 is a circuit diagram of a memory cell array of the magnetic memory device.

Referring to FIG. 2, the memory cell array 10 may include a plurality of first conductive lines, a plurality of second conductive lines, and a plurality of memory cells MC. The first conductive lines may serve as word lines WL, and the second conductive lines may serve as bit lines BL. The memory cells MC may be provided at respective intersections of the first and second conductive lines, thereby forming a two-dimensional arrangement as shown in FIG. 2. Each of the word lines WL may be connected in common to plural ones of the memory cells MC, and the bit lines BL may be respectively connected to the plural ones of the memory cells MC connected to each word line WL. That is, the plural ones of the memory cells MC connected to each word line WL may be connected to the read/write circuit 40, described with reference to FIG. 1, through the bit lines BL.

Each of the memory cells MC may include a memory element ME and a selection element SE. In each of the memory cells MC, the memory element ME may be connected between a corresponding one of the bit lines BL and the selection element SE, and the selection element SE may be connected between the memory element ME and a corresponding one of the word lines WL. The memory element ME may be configured in such a way that electric resistance thereof can be switched to one of at least two resistance values or states using an electric pulse applied thereto.

In example embodiments, the memory element ME may be formed to have a layered structure having an electric resistance that can be changed by a spin transfer process using an electric current passing therethrough. For example, the memory element ME may have a layered structure exhibiting a magneto-resistance property. As an example, the memory element ME may include at least one ferromagnetic material and/or at least one antiferromagnetic material. In example embodiments, the memory element ME may be a magnetic tunnel junction MTJ comprising an interface perpendicular magnetic anisotropy property.

The selection element SE may be configured to selectively control an electric current passing through the memory element ME. For example, the selection element SE may be one of a diode, a pnp bipolar transistor, an npn bipolar transistor, an NMOS (n-channel metal-oxide-semiconductor) field effect transistor (FET), or a PMOS (p-channel metal-oxide-semiconductor) FET. In the case in which the selection element SE is a three-terminal switching device (e.g., a bipolar transistor or a MOSFET), the memory cell array 10 may further include an additional line (not shown) connected to a control electrode or gate of the selection element SE.

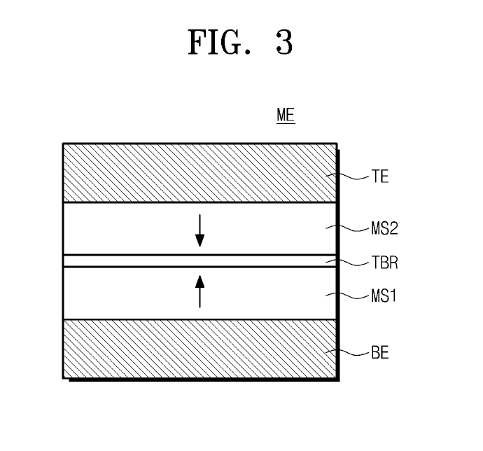

FIG. 3 is a diagram exemplarily illustrating a magnetic tunnel junction (MTJ) memory element ME according to exemplary embodiments disclosed herein.

Referring to FIG. 3, the magnetic tunnel junction MTJ may include a first magnetic layer MS1, a second magnetic layer MS2, and a tunnel barrier TBR therebetween. Each of the first and second magnetic layers MS1 and MS2 may include a magnetic material. The magnetic tunnel junction MTJ may be interposed between a lower electrode BE and an upper electrode TE.

One of the first and second magnetic layers MS1 and MS2 may be configured to have a fixed magnetization direction, which is not changed by an external magnetic field generated under usual environments. In the present specification, for convenience in description, the term ‘pinned layer’ will be used to represent a magnetic layer exhibiting such a fixed magnetization property. By contrast, the other of the first and second magnetic layers MS1 and MS2 may be configured to have a magnetization direction that can be switched by applying an external magnetic field thereto. Hereinafter, the term ‘free layer’ will be used to represent a magnetic layer exhibiting such a switchable magnetization property. In other words, the magnetic tunnel junction MTJ may include at least one free layer and at least one pinned layer separated by the tunnel barrier TBR.

Electric resistance of the magnetic tunnel junction MTJ may be sensitive to a relative orientation of magnetization directions of the free and pinned layers. For example, the electric resistance of the magnetic tunnel junction MTJ may be far greater when the relative orientation is antiparallel than when the relative orientation is parallel. This means that the electrical resistance of the magnetic tunnel junction MTJ can be controlled by changing the magnetization direction of the free layer. In other words, such a difference in electric resistance of the magnetic tunnel junction MTJ may be used to represent two different states of data stored in the memory element ME. In example embodiments, the magnetization direction of the free layer may be changed by a writing operation using a spin-transfer torque effect.

In example embodiments, the magnetic tunnel junction MTJ may be configured in such a way that the first and second magnetic layers MS1 and MS2 serve as the pinned and free layers, respectively. Alternatively, the magnetic tunnel junction MTJ may be configured in such a way that the first and second magnetic layers MS1 and MS2 serve as the free and pinned layers, respectively.

As shown in FIG. 3, each of the first and second magnetic layers MS1 and MS2 may have a magnetization direction that is substantially normal to a top surface of a substrate. In example embodiments, at least one of the first and second magnetic layers MS1 and MS2 may be formed of a material that has an in-plane magnetization property and, in the magnetic tunnel junction MTJ, exhibits a perpendicular magnetization property caused by an external factor. In other words, at least one of the first and second magnetic layers MS1 and MS2 may be configured to have an extrinsic perpendicular magnetization property. According to example embodiments disclosed herein, in one or both of the first and second magnetic layers MS1 and MS2, the extrinsic perpendicular magnetization property may be induced by an interface perpendicular magnetic anisotropy, which will be described below.

For example, in the case in which a metal oxide layer is in contact with a magnetic layer having the in-plane magnetization property, the metal oxide may serve as the external factor, allowing the magnetic layer to have the perpendicular magnetization property. The interface perpendicular magnetic anisotropy may be realized using a layer that is formed of at least one of tantalum oxide, magnesium oxide, ruthenium oxide, iridium oxide, platinum oxide, palladium oxide, titanium oxide, aluminum oxide, magnesium zinc oxide, hafnium oxide, or magnesium boron oxide, but example embodiments disclosed herein may not be limited thereto. In the present specification, the term “interface perpendicular magnetic anisotropy (IPMA)” may refer to the externally-induced perpendicular magnetization property of a magnetic layer with the in-plane magnetization property, which may occur when the magnetic layer is in contact with another layer.

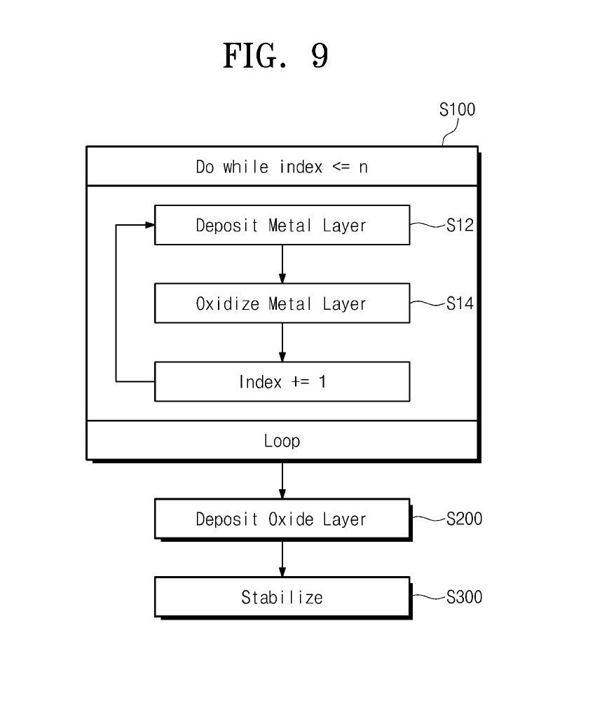

According to exemplary embodiments disclosed herein, the tunnel barrier TBR may serve as the external factor causing the interface perpendicular magnetic anisotropy, for one or both of the first and second magnetic layers MS1 and MS2. However, example embodiments of the disclosed herein may not be limited to this example in which the tunnel barrier TBR is used as the external factor. For example, according to modified example embodiments, in at least one of the first and second magnetic layers MS1 and MS2, the interface perpendicular magnetic anisotropy may be caused by an internal or external layer provided in or outside the first and second magnetic layers MS1 and MS2. Hence, a method of forming the tunnel bather TBR, which will be described with reference to FIGS. 9 through 15, may be applied to realize the modified example embodiments. Further, these applications may be easily achieved by those skilled in the art, based on the following description of example embodiments disclosed herein, and thus, detail description of the applications may be omitted below.

In the case in which the first or second magnetic layer MS1 or MS2 is used as the free layer, the free layer may be provided in the form of a single or multi-layered structure including at least one layer of cobalt, iron, nickel, or alloys thereof. As an example, the free layer may be a single or multi-layered structure including at least one layer that is formed of Fe, Co, Ni, CoFe, NiFe, NiFeB, CoFeB, CoFeBTa, CoHf, or CoZr. In other example embodiments, the free layer may be provided in the form of a multi-layered structure including a pair of magnetic layers and a non-magnetic metal layer interposed therebetween. As an example, the free layer may include a pair of layers made of a cobalt-iron-boron (CoFeB) alloy and a tantalum or tungsten layer interposed therebetween. However, these materials are merely enumerated as examples for providing better understanding of example embodiments disclosed herein, and example embodiments may not be limited thereto.

In the case in which the first or second magnetic layer MS1 or MS2 is used as the pinned layer, the pinned layer may be provided in the form of a single or multi-layered structure including at least one layer of cobalt, iron, nickel, or alloys thereof. For example, the pinned layer may be a single or multi-layered structure including at least one layer that is formed of Fe, Co, Ni, CoFe, NiFe, NiFeB, CoFeB, CoFeBTa, CoHf, or CoZr. In example embodiments, the pinned layer may further include at least one of non-magnetic metal materials (e.g., tungsten and platinum).

In the case in which one of the first and second magnetic layers MS1 and MS2 has the extrinsic perpendicular magnetization property realized using the interface perpendicular magnetic anisotropy, the other magnetic layer may be configured to include at least one of materials or layered structures having the perpendicular magnetization property. Although embodiments disclosed herein may not be limited thereto, the material or layered structure having the perpendicular magnetization property may be at least one of the followings: a) cobalt iron terbium (CoFeTb), in which the relative content of Tb is 10% or greater; b) cobalt iron gadolinium (CoFeGd), in which the relative content of Gd is 10% or greater; c) cobalt iron dysprosium (CoFeDy); d) FePt with the L1₀ structure; e) FePd with the L1₀ structure; f) CoPd with the L1₀ structure; g) CoPt with the L1₀ structure; h) CoPt with the hexagonal close packing (HCP) structure; i) alloys containing at least one of materials presented in items of a) to h), and/or j) a multi-layered structure including alternatingly-stacked magnetic and non-magnetic layers. For example, the multi-layered structure including the alternatingly-stacked magnetic and non-magnetic layers may include at least one of (Co/Pt)n, (CoFe/Pt)n, (CoFe/Pd)n, (CoP)n, (Co/Ni)n, (CoNi/Pt)n, (CoCr/Pt)n, and/or (CoCr/Pd)n, in which the subscript n denotes the stacking number.

The tunnel barrier TBR may include at least one of, for example, tantalum oxide, magnesium oxide, ruthenium oxide, iridium oxide, platinum oxide, palladium oxide, titanium oxide, aluminum oxide, magnesium zinc oxide, hafnium oxide, or magnesium boron oxide.

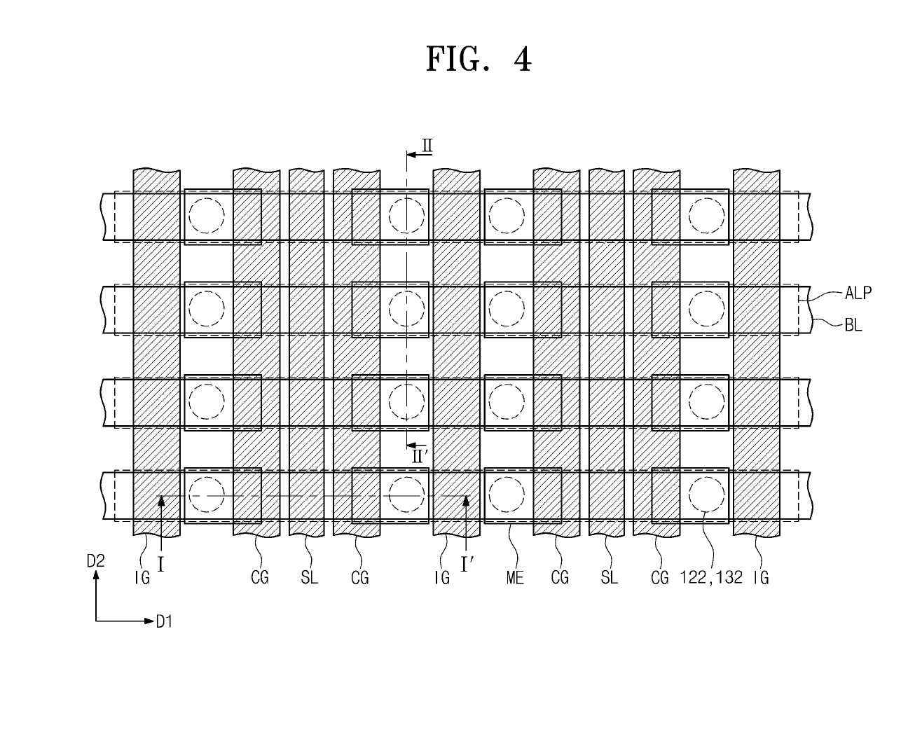

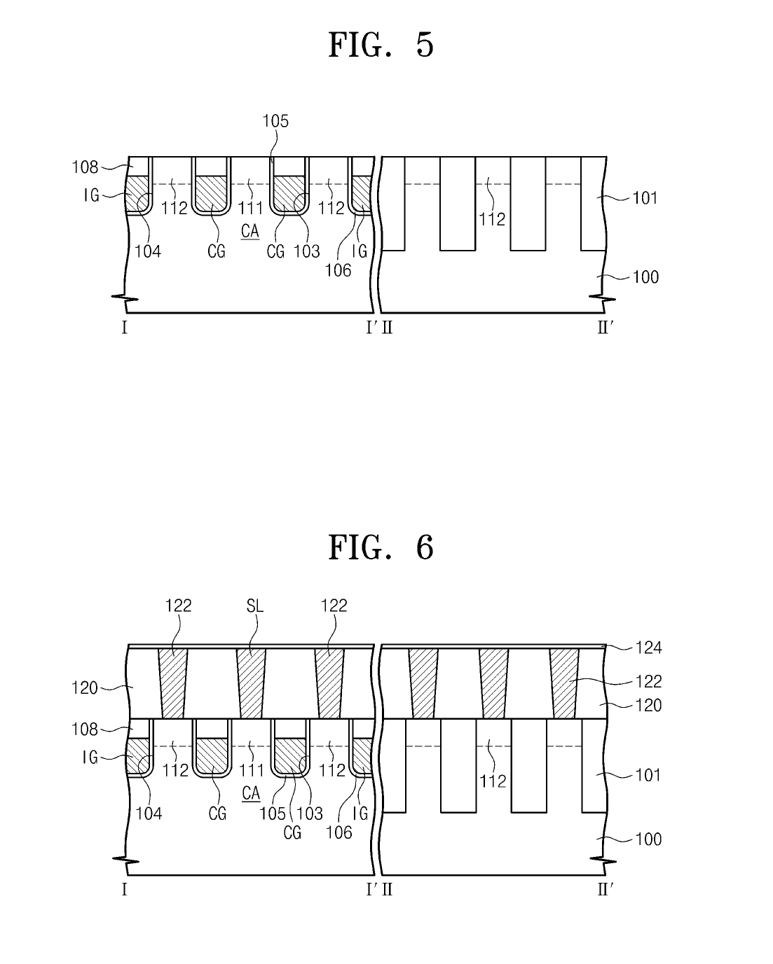

FIG. 4 is a plan view provided to illustrate a method of fabricating a memory device according to exemplary embodiments disclosed herein, and FIGS. 5 through 8 are sectional views illustrating a method of fabricating a memory device according to exemplary embodiments disclosed herein. In detail, FIGS. 5 through 8 are sectional views taken along lines I-I′ and II-II′ of FIG. 4.

Referring to FIGS. 4 and 5, the semiconductor substrate 100 may be prepared. The semiconductor substrate 100 may be a silicon substrate, a germanium substrate, and/or a silicon-germanium substrate. The semiconductor substrate 100 may have the first conductivity type.

Device isolation patterns 101 may be formed on the semiconductor substrate 100 to define active line patterns ALP. The active line patterns ALP may be formed to be substantially parallel to a first direction D1 of FIG. 4. The device isolation patterns 101 may be formed using a shallow trench isolation (STI) process.

The active line patterns ALP and the device isolation patterns 101 may be patterned to form the gate and isolation recess regions 103 and 104 extending substantially parallel to a second direction D2 of FIG. 4. The isolation recess regions 104 may be formed to section each active line pattern ALP into a plurality of active patterns CA. The gate recess regions 103 may be formed to cross the cell active patterns CA arranged substantially parallel to the second direction D2. The gate and isolation recess regions 103 and 104 may be formed to have depths that are less than those of the device isolation patterns 101.

A cell gate dielectric layer 105 may be formed to conformally cover an inner surface of each gate recess region 103. Similarly, an isolation gate dielectric layer 106 may also be formed to conformally cover an inner surface of each isolation recess region 104. In example embodiments, the cell and isolation gate dielectric layers 105 and 106 may be simultaneously formed using the same process. For example, the cell and isolation gate dielectric layers 105 and 106 may be silicon oxide layers, which are formed by performing a thermal oxidation process on the semiconductor substrate 100. Alternatively, the cell and isolation gate dielectric layers 105 and 106 may be formed of or include at least one of silicon oxide, silicon nitride, silicon oxynitride, or high-k dielectric materials including insulating metal oxides (e.g., hafnium oxide or aluminum oxide).

Next, a first conductive layer may be formed to fill the gate and isolation recess regions 103 and 104. The first conductive layer may be formed of or include at least one of doped semiconductor materials (e.g., doped silicon and so forth), metals (e.g., tungsten, aluminum, titanium, or tantalum), conductive metal nitrides (e.g., titanium nitride, tantalum nitride, or tungsten nitride), or metal-semiconductor compounds (e.g., metal silicide). The first conductive layer may be etched to form a cell gate electrode CG in each gate recess region 103 and an isolation gate electrode IG in each isolation recess region 104. The cell and isolation gate electrodes CG and IG may be recessed to have top surfaces that are lower than that of the semiconductor substrate 100.

Gate mask patterns 108 may be formed on the cell and isolation gate electrodes CG and IG to fill the remaining spaces of the gate and isolation recess regions 103 and 104 provided with the cell and isolation gate electrodes CG and IG. The gate mask patterns 108 may be formed of or include at least one of silicon oxide, silicon nitride, or silicon oxynitride.

First and second doped regions 111 and 112 may be formed in portions of the cell active pattern CA, which are positioned at both sides of the cell gate electrode CG. The first and second doped regions 111 and 112 may be formed using an ion implantation process and may have a second conductivity type different from the first conductivity type. Furthermore, the first and second doped regions 111 and 112 may be formed at a level higher than bottom level of the cell gate electrode CG.

Referring to FIGS. 4 and 6, a first interlayered insulating layer 120 may be formed on the semiconductor substrate 100. The first interlayered insulating layer 120 may be formed of silicon oxide. The first interlayered insulating layer 120 may be patterned to form cell holes and source grooves.

Thereafter, a second conductive layer may be formed to fill the cell holes and the source grooves. The second conductive layer may be formed of or include at least one of doped semiconductor materials (e.g., doped silicon), metals (e.g., tungsten, aluminum, titanium, or tantalum), conductive metal nitrides (e.g., titanium nitride, tantalum nitride, or tungsten nitride), or metal-semiconductor compounds (e.g., metal silicide). A planarization process may be performed on the second conductive layer, until the first interlayered insulating layer 120 is exposed. Accordingly, first contact plugs 122 may be respectively formed in the cell holes and source lines SL may be respectively formed in the source grooves. The first contact plugs 122 may be respectively connected to the second doped regions 112, and each of the source lines SL may be connected in common to the first doped regions 111 arranged along the second direction D2. In example embodiments, ohmic patterns (not shown) may be formed between the source lines SL and the first doped regions 111 and between the first contact plugs 122 and the second doped regions 112. The ohmic patterns may be formed of or include at least one of metal-semiconductor compounds including a metal silicide (e.g., cobalt silicide or titanium silicide).

Thereafter, a capping insulating layer 124 may be formed to cover the first interlayered insulating layer 120, the first contact plugs 122, and the source lines SL. The capping insulating layer 124 may be formed of or include silicon nitride and/or silicon oxynitride.

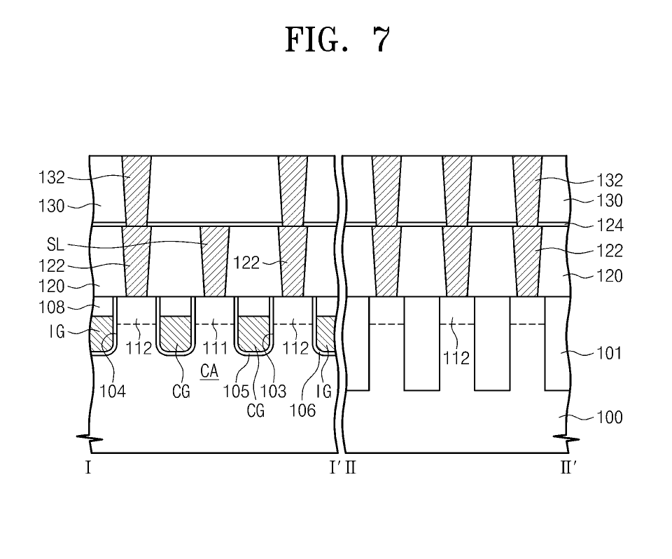

Referring to FIGS. 4 and 7, a second interlayered insulating layer 130 may be formed on the capping insulating layer 124. The second interlayered insulating layer 130 may be formed of silicon oxide. Second contact plugs 132 may be formed to penetrate the second interlayered insulating layer 130 and the capping insulating layer 124. In example embodiments, the second contact plugs 132 may be formed by the same method as and of the same material as the first contact plugs 122. The second contact plugs 132 may be electrically and respectively connected to the second doped regions 112 through the first contact plugs 122. In certain embodiments, additional ohmic patterns (not shown) may be formed between the second contact plugs 132 and the first contact plugs 122. The additional ohmic patterns may be formed of or include at least one of metal-semiconductor compounds including a metal silicide (e.g., cobalt silicide or titanium silicide).

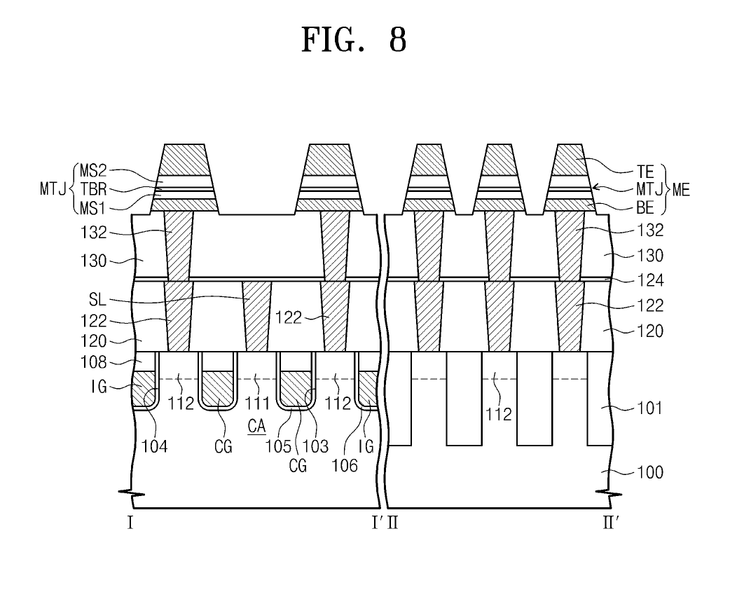

Referring to FIGS. 4 and 8, a memory layer may be formed on the second interlayered insulating layer 130. In example embodiments, the memory layer may include lower electrode layer, magnetic tunnel junction layer, and upper electrode layer sequentially stacked on the second interlayered insulating layer 130.

The memory layer may be patterned to form memory devices ME that are respectively connected to the second contact plugs 132. Each of the memory devices ME may include a lower electrode BE, a magnetic tunnel junction MTJ, and an upper electrode TE. The magnetic tunnel junction MTJ may include a first magnetic layer MS1, a second magnetic layer MS2, and a tunnel barrier TBR interposed therebetween, as described with reference to FIG. 3.

In the case in which the first or second magnetic layer MS1 or MS2 is used as the free layer, the free layer may be provided in the form of a single or multi-layered structure including at least one layer of cobalt, iron, nickel, or alloys thereof. As an example, the free layer may be a single or multi-layered structure including at least one layer that is formed of Fe, Co, Ni, CoFe, NiFe, NiFeB, CoFeB, CoFeBTa, CoHf, or CoZr. In other example embodiments, the free layer may be provided in the form of a multi-layered structure including a pair of magnetic layers and a non-magnetic metal layer interposed therebetween. As an example, the free layer may include a pair of layers made of a cobalt-iron-boron (CoFeB) alloy and a tantalum or tungsten layer interposed therebetween. However, these materials are merely enumerated as examples for providing better understanding of example embodiments disclosed herein, and example embodiments may not be limited thereto.

In the case in which the first or second magnetic layer MS1 or MS2 is used as the pinned layer, the pinned layer may be provided in the form of a single or multi-layered structure including at least one layer of cobalt, iron, nickel, or alloys thereof. For example, the pinned layer may be a single or multi-layered structure including at least one layer, which is formed of Fe, Co, Ni, CoFe, NiFe, NiFeB, CoFeB, CoFeBTa, CoHf, or CoZr. In example embodiments, the pinned layer may further include at least one of non-magnetic metal materials (e.g., tungsten and platinum).

In the case in which one of the first and second magnetic layers MS1 and MS2 has the extrinsic perpendicular magnetization property realized using the interface perpendicular magnetic anisotropy, the other magnetic layer may be configured to include at least one of materials or layered structures having the perpendicular magnetization property. Although the embodiments disclosed herein may not be limited thereto, the material or layered structure having the perpendicular magnetization property may be at least one of the followings: a) cobalt iron terbium (CoFeTb), in which the relative content of Tb is 10% or greater; b) cobalt iron gadolinium (CoFeGd), in which the relative content of Gd is 10% or greater; c) cobalt iron dysprosium (CoFeDy); d) FePt with the L10 structure; e) FePd with the L10 structure; f) CoPd with the L10 structure; g) CoPt with the L10 structure; h) CoPt with the hexagonal close packing (HCP) structure; i) alloys containing at least one of materials presented in items of a) to h), and/or j) a multi-layered structure including alternatingly-stacked magnetic and non-magnetic layers.

The tunnel barrier TBR may include, for example, at least one of tantalum oxide, magnesium oxide, ruthenium oxide, iridium oxide, platinum oxide, palladium oxide, titanium oxide, aluminum oxide, magnesium zinc oxide, hafnium oxide, or magnesium boron oxide.

Hereinafter, a method of forming a metal oxide layer, according to example embodiments disclosed herein, will be described with reference to FIGS. 9 through 15. The method of forming the metal oxide layer may be used to form the tunnel barrier TBR on the first magnetic layer MS1. However, example embodiments are not limited to the present embodiments disclosed herein in which this method is used to form the tunnel bather TBR. For example, this method may be used to realize modified embodiments in which the interface perpendicular magnetic anisotropy is realized by a metal oxide layer provided in or outside the first and second magnetic layers MS1 and MS2. Furthermore, if there is a need to improve uniformity in electric and/or physical property (e.g., in electric resistance and deposition thickness) of a metal oxide layer, this method may be used to meet such a need. Further, these applications may be easily achieved by those skilled in the art, based on the following description of example embodiments disclosed herein, and thus, detail description of the applications may be omitted below.

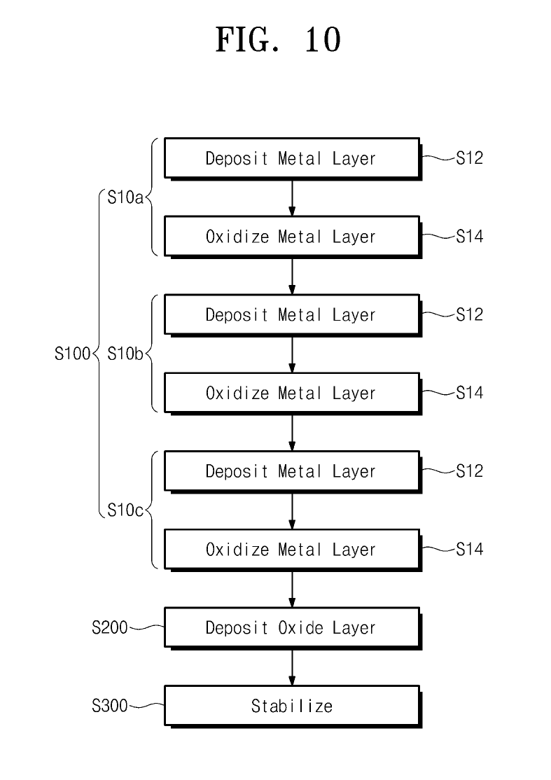

FIG. 9 is a flow chart illustrating a method of forming a metal oxide according to exemplary embodiments disclosed herein, and FIG. 10 is a flow chart illustrating an example of the method of forming a metal oxide according to exemplary embodiments disclosed herein.

Referring to FIG. 9, a method of forming a metal oxide layer may include a post-oxidation process S100, a pre-oxidation process S200, and a stabilizing process S300, which may be performed in a sequential manner. In the case of the post-oxidation process S100, a metal oxide is formed after a deposition process, whereas in the case of the pre-oxidation process S200, a metal oxide is prepared before a deposition process. That is, the pre-oxidation process S200 may include depositing a prepared metal oxide.

For example, the post-oxidation process S100 may include a metal deposition step of depositing a metal layer (in S12) and a metal oxidation step of oxidizing the deposited metal layer (in S14).

The metal deposition step S12 may include forming a metal layer on a substrate using a DC sputtering process in which a DC power is supplied. In example embodiments, in the DC sputtering process, at least one of metallic materials (e.g., tantalum, magnesium, ruthenium, iridium, platinum, palladium, titanium, aluminum, magnesium zinc, hafnium, or magnesium boron) may be used as a sputtering target material, and at least one of argon or krypton may be used as a sputtering source. Further, in the DC sputtering process, the DC power may be controlled to have an output power ranging from about 20 W to about 100 W. Alternatively, in the DC sputtering process, the DC power may be controlled to have an output power ranging from about 30 W to about 60 W. Although not limited to the following examples, the DC sputtering process may be performed at room temperature.

The metal oxidation step S14 may include supplying oxygen-containing gas (e.g., O₂) onto the metal layer that is formed by the metal deposition step S12. In the case in which the oxygen-containing gas is O₂ gas, the oxygen-containing gas may be supplied on the metal layer at a flow rate of about 0.1 sccm to about 200 sccm for about 0.5 seconds to about 10 seconds. Also, although not limited to the following examples, the metal oxidation step S14 may be performed at a temperature ranging from about 15° C. to about 50° C. For example, the metal oxidation step S14 may be performed at room temperature. In the meantime, the afore-mentioned process conditions on supply time, flow rate, and temperature may be changed in consideration of a kind of a process gas to be used, and such a change in the process conditions may be optimized in an empirical manner (e.g., a series of experiments to be made). In this sense, example embodiments disclosed herein are not limited to the afore-mentioned process conditions.

According to exemplary embodiments disclosed herein, the post-oxidation process S100 may be configured in such a way that a process cycle consisting of the metal deposition S12 and the metal oxidation step S14 is performed at least once during each post-oxidation process S100. For example, as shown in FIG. 10, the post-oxidation process S100 may include a first process cycle S10a, a second process cycle S10b, and a third process cycle S10c, which are performed in a sequential manner, and each of which includes the metal deposition step S12 and the metal oxidation step S14.

In the case in which the post-oxidation process S100 includes a plurality of process cycles (e.g., S10a, S10b, and S10c), there may be a difference in process condition between the process cycles S10a, S10b, and S10c. For example, one or both of the metal deposition step S12 and the metal oxidation step S14 may be performed under a quality-oriented condition in an early process cycle and under a productivity-oriented condition in a late process cycle. Here, when compared with the productivity-oriented condition, the quality-oriented condition may be set up in a manner of reducing energy supplied per unit time and increasing process duration time. When compared with the quality-oriented condition, the productivity-oriented condition may be set up in a manner of increasing energy supplied per unit time and decreasing process duration time.

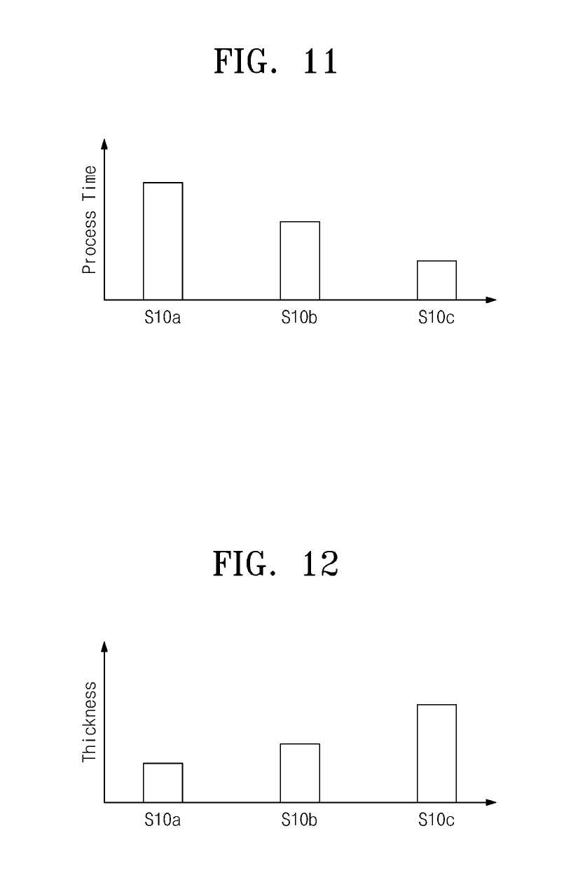

For example, as shown in FIG. 11, the post-oxidation process S100 may be performed in such a way that the process duration time decreases with the number of repetition of the process cycle. In other words, the process duration time may decrease as the process cycle is repeated. Here, the process duration time may be a sum of the duration time of the DC sputtering process for the metal deposition step S12 and the supplying time of the oxygen-containing gas for the metal oxidation step S14.

As shown in FIG. 12, the post-oxidation process S100 may be performed in such a way that a thickness of the metal layer to be formed by each process cycle increases with the number of repetition of the process cycle. In other words, the thickness of the metal layer to be formed by each process cycle may increase as the process cycle is repeated. In example embodiments, in the first process cycle S10a of the post-oxidation process S100, the metal layer may be formed to have an effective deposition thickness ranging from about 0.1 Ångströms to about 1.5 Ångströms. Here, the effective deposition thickness may be defined as deposition volume per unit area, and thus, an effective deposition thickness less than 1 Ångström means that metal atoms constituting the metal layer are deposited to form separated islands on the magnetic layer. In example embodiments, in the first process cycle S10a, the effective deposition thickness of the metal layer may be about 1 Ångström.

Here, for the post-oxidation process S100, there is no need to satisfy both of the conditions depicted in FIGS. 11 and 12. For example, the post-oxidation process S100 may be performed in such a way that, when the number of repetition of the process cycles increases, the thickness of the metal layer increases, but the process duration time is not changed. In other words, as the process is repeated, the thickness of the metal layer may increase, but the process duration time may not be changed.

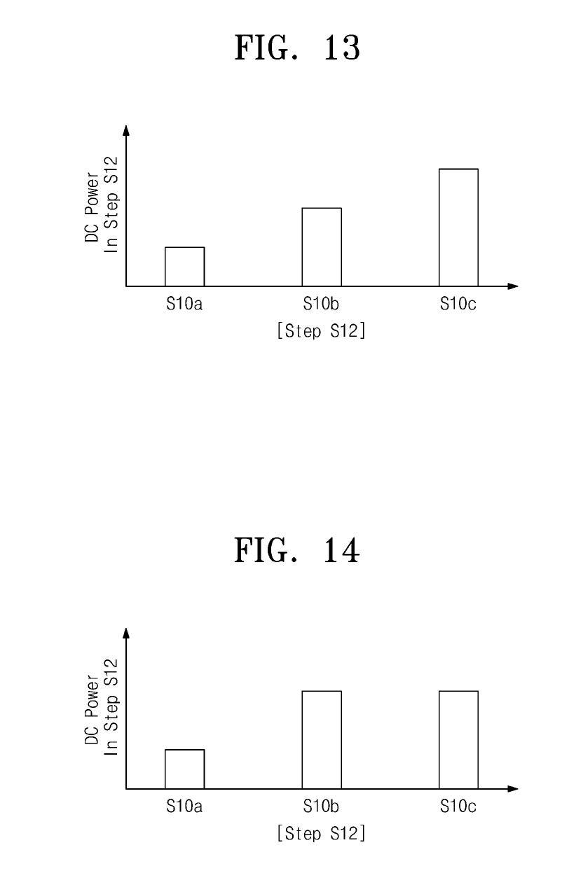

Furthermore, as shown in FIG. 13, the post-oxidation process S100 may be performed in such a way that an output level of the DC power to be supplied in the metal deposition step S12 increases with the number of repetition of the process cycle. In other words, the output level of the DC power to be supplied in the metal deposition step S12 may increase, as the process cycle is repeated. Although, in order to reduce complexity in the drawings, FIG. 13 exemplarily illustrates a case in which the DC power has a linearly increasing output level, example embodiments disclosed herein may not be limited thereto. For example, the output level of the DC power may increase, but such an increment may increase or decrease, when the number of repetition of the process cycles increases. In other words, the output level of the DC power may increase, but such an increment may increase or decrease, as the process is repeated.

Alternatively, as shown in FIG. 14, the output level of the DC power in the second and third process cycles S10b and S10c may be substantially the same and may be greater than that in the first process cycle S10a. Similarly, the process conditions described with reference to FIGS. 11 through 13 and 15 may also be modified in the same manner as the graph depicted in FIG. 14 (for example, in such a way that at least two process cycles have substantially the same level).

In the case in which, as shown in FIGS. 13 and 14, the metal deposition step S12 of the first process cycle S10a is performed using a DC power with a low output level, it is possible to reduce damage on the magnetic layer in the process of forming the metal layer on the magnetic layer.

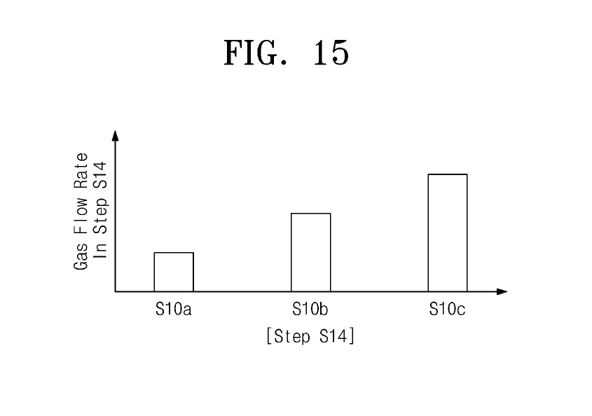

As shown in FIG. 15, the metal oxidation step S14 of the post-oxidation process S100 may be performed in such a way that a flow rate of the oxygen-containing gas increases with the number of repetition of the process cycle. In other words, the flow rate of the oxygen-containing gas may increase, as the process cycle is repeated. Although, in order to reduce complexity in the drawings, FIG. 15 exemplarily illustrates a case in which the oxygen-containing gas is supplied at a linearly increasing flow rate, example embodiments disclosed herein may not be limited thereto. For example, the flow rate of the oxygen-containing gas may increase, but such an increment may increase or decrease when the number of repetition of the process cycles increases. In other words, the flow rate of the oxygen-containing gas may increase, but such an increment may increase or decrease as the process cycle is repeated.

Similar to the graph of FIG. 14, the flow rates of the oxygen-containing gas in the second and third process cycles S10b and S10c may be substantially the same and may be greater than that in the first process cycle S10a. In certain embodiments, the flow rate of the oxygen-containing gas in the third process cycle S10c may be increased to about 100 sccm.

The pre-oxidation process S200 may include a step of forming a metal oxide layer using an RF sputtering process, in which at least one of metal oxides is used as a sputtering target material. The metal oxides for the pre-oxidation process S200 may include at least one of tantalum oxide, magnesium oxide, ruthenium oxide, iridium oxide, platinum oxide, palladium oxide, titanium oxide, aluminum oxide, magnesium zinc oxide, hafnium oxide, or magnesium boron oxide.

Since the pre-oxidation process S200 is performed after the post-oxidation process S100, the metal oxide layer formed by the pre-oxidation process S200 may be formed to cover the metal oxide layer formed by the post-oxidation process S100. The pre-oxidation process S200 may be performed to form the metal oxide having a thickness ranging from 3 to 10 Ångström.

The RF sputtering process of the pre-oxidation process S200 may be performed using argon or krypton as a sputtering source. In the case in which argon is used as the sputtering source, the RF sputtering process may be performed under a power condition of about 200 W and an argon flow rate condition of about 200 sccm for 400 to 800 seconds. In the case in which krypton is used as the sputtering source, the RF sputtering process may be performed under a power condition of about 100 W and a krypton flow rate condition of about 50 sccm for about 1400 seconds to about 1900 seconds. In the meantime, the afore-mentioned process conditions on supply time, flow rate, and temperature may be changed in consideration of a kind of a process gas to be used, and such a change in the process condition may be optimized in an empirical manner (e.g., a series of experiments). In this sense, the pre-oxidation process S200 is not limited to the afore-mentioned process conditions for the RF sputtering process.

According to other example embodiments disclosed herein, the pre-oxidation process S200 may be performed at least once before the stabilizing process S300. According to still other example embodiments disclosed herein, the pre-oxidation process S200 may be omitted, and the stabilizing process S300 may be performed after the post-oxidation process S100.

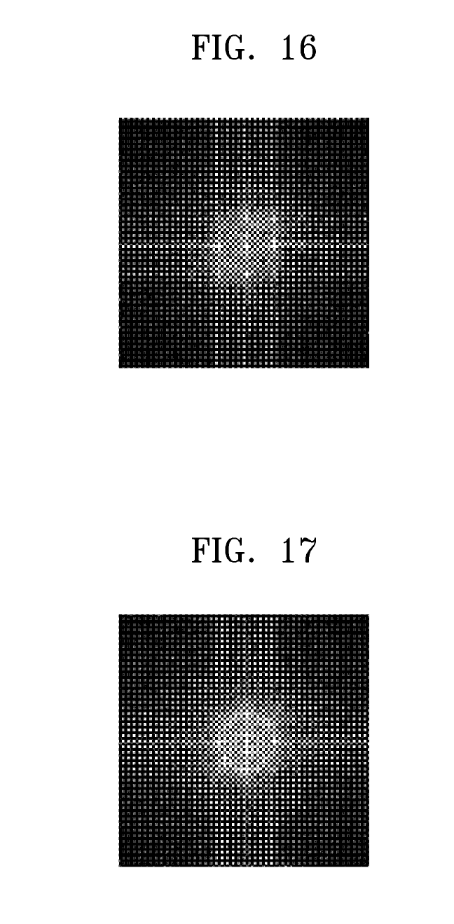

The stabilizing process S300 may include a low-temperature annealing step, which may be performed at about 50° C. to about 200° C. for about 10 seconds to about 1000 seconds. The stabilizing process S300 may contribute to crystallize the metal oxide layer, which are formed by the post-oxidation process S100 and/or the pre-oxidation process S200. For example, the metal oxide layer formed by the afore-described method may have a body centered cubic (BCC) lattice structure, as will be described with reference to FIG. 16.

FIG. 16 is transmission electron microscope (TEM) image showing diffraction pattern obtained from metal oxides according to an experimental example. FIG. 17 is transmission electron microscope (TEM) image showing diffraction pattern obtained from metal oxides according to a comparative example. For example, FIG. 16 is a TEM image showing diffraction pattern of a magnesium oxide layer that was formed using the method of FIGS. 9 and 10. FIG. 17 is a TEM image showing diffraction pattern of a magnesium oxide layer that was formed using a method according to a comparative example. The magnesium oxide layer of the comparative example was formed using only an RF sputtering process. In the case of using the method of FIGS. 9 and 10, the resulting magnesium oxide layer was formed to have a BCC lattice structure, as shown in FIG. 16. By contrast, in the case of using only the RF sputtering process, the resulting magnesium oxide layer did not have the BCC lattice structure, as shown in FIG. 17. In other words, FIG. 16 shows that, by using the layer-forming method according to example embodiments disclosed herein, it is possible to obtain a crystallized metal oxide layer.

FIGS. 18, 19, and 20 are graphs showing electric characteristics of magnetic tunnel junctions according to the experimental and comparative examples. In detail, FIGS. 18, 19, and 20 are graphs showing tunnel magnetoresistance (TMR), resistance-area product (RA), and RA standard deviation characteristics, respectively, of the magnetic tunnel junctions. Data of the experimental example, depicted as Type 1, were obtained from magnesium oxide formed by the method described with reference to FIGS. 9 and 10. By contrast, data of a comparative example 1, depicted as Type 2, were obtained from magnesium oxide formed by depositing a magnesium layer and performing one cycle of an oxidation process, and data of a comparative example 2, depicted as Type 3, were obtained from magnesium oxide formed by performing only an RF sputtering process. Further, data shown in FIGS. 18, 19, and 20 were obtained from magnetic memory chips, each including a plurality of magnetic tunnel junctions. In particular, FIG. 20 shows values (i.e., in-chip standard deviations) obtained from respective chips.

Referring to FIG. 18, a TMR ratio of a magnetic tunnel junction was about 150% to about 200% for the experimental example, about 75% to about 125% for the comparative example 1, and about 125% to about 225% for the comparative example 2. That is, the experimental example and the comparative example 2 were superior to the comparative example 1 in terms of the TMR ratio property of the magnetic tunnel junction.

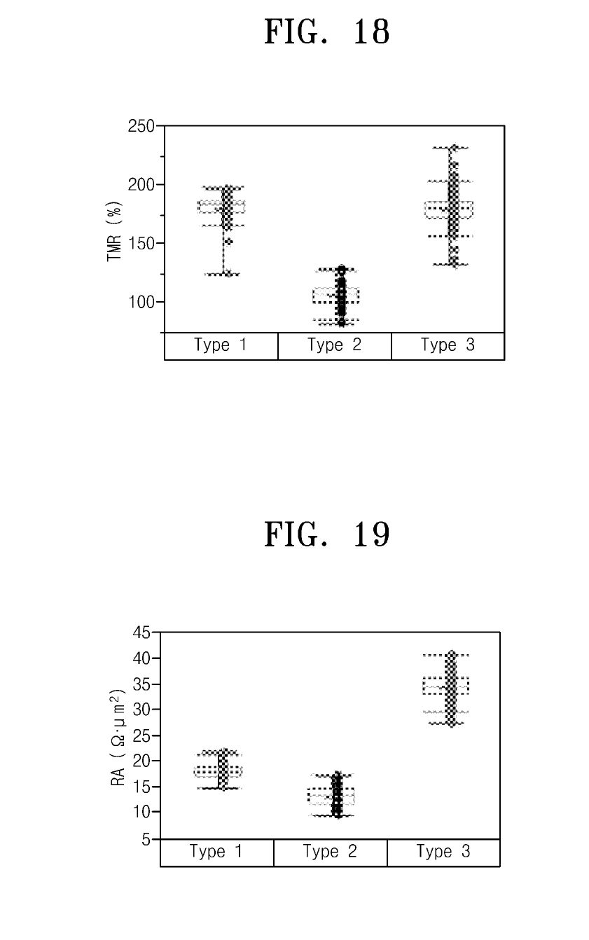

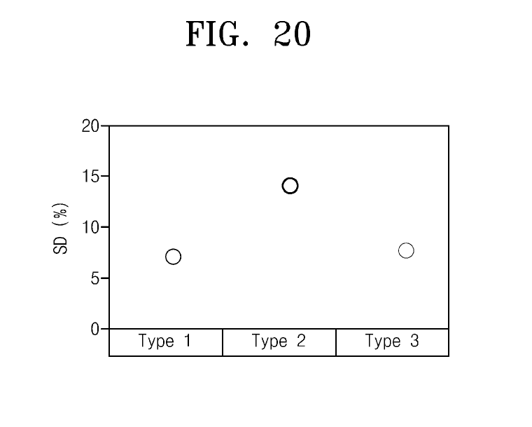

Referring to FIG. 19, an RA value of a magnesium oxide layer was about 15-22 Ω·μm² for the experimental example, about 10 Ω·μm² to about 16 Ω·μm² for the comparative example 1, and about 27 Ω·μm² to about 41 Ω·μm² for the comparative example 2. That is, the experimental example and the comparative example 1 were superior to the comparative example 2 in terms of the RA value of the magnesium oxide layer.

Referring to FIG. 20, an RA standard deviation of the magnesium oxide layer was about 7% for the experimental example, about 14% for the comparative example 1, and about 8% for the comparative example 2. That is, the experimental example and the comparative example 2 were superior to the comparative example 1, in terms of the RA standard deviation of the magnesium oxide layer.

In sum, FIGS. 18 through 20 show that, if the method according to example embodiments disclosed herein is used to form a metal oxide layer, it is possible to improve not only a TMR property of a magnetic tunnel junction, but also RA and its standard deviation characteristics of a tunnel barrier.

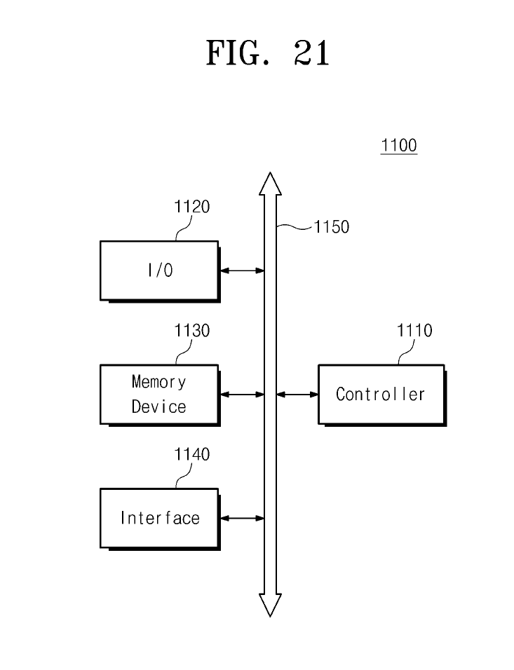

FIG. 21 is a schematic block diagram illustrating an example of electronic systems including a semiconductor memory device according to example embodiments disclosed herein.

Referring to FIG. 21, an electronic system 1100 according to example embodiments disclosed herein may include a controller 1110, an input/output (I/O) unit 1120, a memory device 1130, an interface unit 1140 and a data bus 1150. At least two of the controller 1110, the I/O unit 1120, the memory device 1130 and the interface unit 1140 may communicate with each other via the data bus 1150. The data bus 1150 may correspond to a path through which electrical signals are transmitted. The memory device 1130 may be configured to include one of magnetic memory devices according to example embodiments disclosed herein.

The controller 1110 may include at least one of a microprocessor, a digital signal processor, a microcontroller or another logic device. The other logic device may have a similar function to any one of the microprocessor, the digital signal processor and the microcontroller. The I/O unit 1120 may include a keypad, a keyboard or a display unit. The memory device 1130 may store data and/or commands. The interface unit 1140 may transmit electrical data to a communication network or may receive electrical data from a communication network. The interface unit 1140 may operate by wireless or cable. For example, the interface unit 1140 may include an antenna for wireless communication or a transceiver for cable communication. The electronic system 1100 may further include a fast DRAM device and/or a fast SRAM device that acts as a cache memory for improving an operation of the controller 1110.

The electronic system 1100 may be applied to a personal digital assistant (PDA), a portable computer, a web tablet, a wireless phone, a mobile phone, a digital music player, a memory card or an electronic product. The electronic product may receive or transmit information data wirelessly.

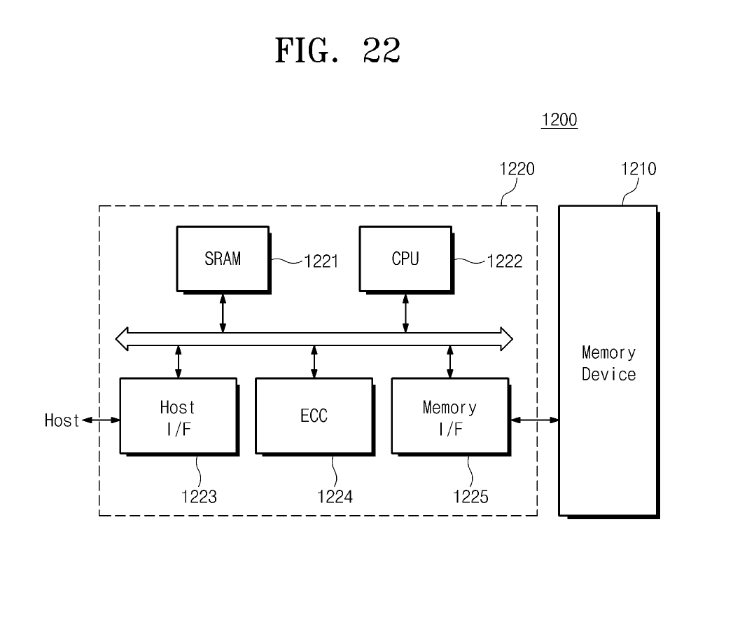

FIG. 22 is a schematic block diagram illustrating an example of memory cards including a semiconductor memory device according to example embodiments disclosed herein.

Referring to FIG. 22, a memory card 1200 according to example embodiments disclosed herein may include a memory device 1210. The memory device 1210 may include at least one of the magnetic memory devices according to the afore-described embodiments disclosed herein. In other embodiments, the memory device 1210 may further include a memory device, which is of a different type from the memory devices according to the afore-described embodiments disclosed herein. For example, the memory device 1210 may further include a nonvolatile memory device and/or a static random access memory (SRAM) device. The memory card 1200 may include a memory controller 1220 that controls data communication between a host and the memory device 1210. The memory device 1210 may be configured to include at least one of the magnetic memory devices according to example embodiments disclosed herein.

The memory controller 1220 may include a central processing unit 1222 that controls overall operations of the memory card 1200. In addition, the memory controller 1220 may include an SRAM device 1221 used as an operation memory of the central processing unit 1222. Moreover, the memory controller 1220 may further include a host interface unit 1223 and a memory interface unit 1225. The host interface unit 1223 may be configured to include a data communication protocol between the memory card 1200 and the host. The memory interface unit 1225 may connect the memory controller 1220 to the memory device 1210. The memory controller 1220 may further include an error check and correction (ECC) block 1224. The ECC block 1224 may detect and correct errors of data which are read out from the memory device 1210. The memory card 1200 may further include a read only memory (ROM) device that stores code data to interface with the host. The memory card 1200 may be used as a portable data storage card. Alternatively, the memory card 1200 may be provided in the form of solid state disks (SSD) instead of hard disks of computer systems.

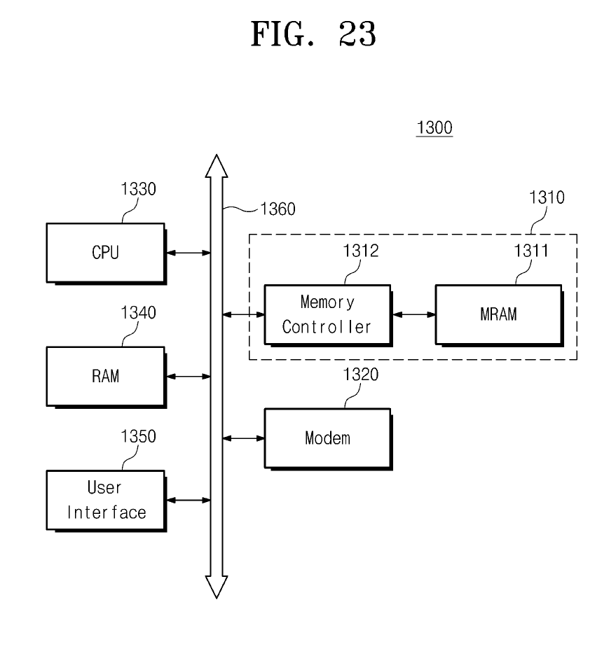

FIG. 23 is a schematic block diagram illustrating an example of information processing systems including a magnetic memory device according to example embodiments disclosed herein.

Referring to FIG. 23, an information processing system 1300 includes a memory system 1310, which may include at least one of the magnetic memory devices according to example embodiments disclosed herein. The information processing system 1300 also includes a modem 1320, a central processing unit (CPU) 1330, a RAM 1340, and a user interface 1350, which may be electrically connected to the memory system 1310 via a system bus 1360. The memory system 1310 may include a memory device 1311 and a memory controller 1312 controlling an overall operation of the memory device 1311. Data processed by the CPU 1330 and/or input from the outside may be stored in the memory system 1310. Here, the memory system 1310 may constitute a solid state drive SSD, and thus, the information processing system 1300 may be able to store reliably a large amount of data in the memory system 1310. This increase in reliability enables the memory system 1310 to conserve resources for error correction and realize a high speed data exchange function. Although not shown in the drawing, it will be apparent to those of ordinary skill in the art that the information processing system 1300 may be also configured to include an application chipset, a camera image processor (CIS), and/or an input/output device.

According to example embodiments disclosed herein, a method is provided to form a metal oxide layer using at least one post-oxidation process. For example, a process of forming the metal oxide layer may include repeating the post-oxidation process several times. Accordingly, it is possible to easily control an interfacial property between a lower magnetic layer and the metal oxide layer and reduce damage to the lower magnetic layer. As a result, the metal oxide layer can be formed to have an improved crystalline property and a lower RA property.

By using the method of forming the metal oxide layer, it is possible to increase a TMR ratio of an interface perpendicular magnetic anisotropic magnetic tunnel junction and reduce a uniform and low RA value of the tunnel barrier. Accordingly, the magnetic memory device can have improved electric characteristics (e.g., a reduced write current density and improved in-chip resistance uniformity).

While example embodiments disclosed herein have been particularly shown and described, it will be understood by one of ordinary skill in the art that variations in form and detail may be made therein without departing from the scope of the attached claims.

1. A method of forming an interface perpendicular magnetic anisotropic (IPMA) magnetic tunnel junction including a magnetic layer and a tunnel insulating layer,
wherein forming the tunnel insulating layer comprises sequentially performing a post-oxidation process and a stabilizing process, and
the post-oxidation process comprises performing at least once a process cycle, the process cycle comprising depositing a metal layer on the magnetic layer and oxidizing the metal layer.

2. The method of claim 1, wherein the depositing of the metal layer comprises a DC sputtering process using a DC power.

3. The method of claim 2, wherein performing the post-oxidation process comprises repeating the process cycle a predetermined number of times, and
wherein an output level of the DC power in the DC sputtering process increases as the process cycle is repeated.

4. The method of claim 2, wherein performing the post-oxidation process comprises repeating the process cycle a predetermined number of times, and
wherein a deposition thickness of the metal layer increases as the process cycle is repeated.

5. The method of claim 2, wherein performing the post-oxidation process comprises repeating the process cycle a predetermined number of times, and
wherein an output level of the DC power in the DC sputtering process and a deposition thickness of the metal layer increase as the process cycle is repeated.

6. The method of claim 2, wherein the DC sputtering process is performed using at least one of tantalum, magnesium, ruthenium, iridium, platinum, palladium, titanium, aluminum, magnesium zinc, hafnium, or magnesium boron as a sputtering target material and using at least one of argon or krypton as a sputtering source.

7. The method of claim 2, wherein the DC sputtering process is performed using a DC power ranging from about 20 W to about 100 W.

8. The method of claim 1, wherein performing the post-oxidation process comprises repeating the process cycle a predetermined number of times, and
wherein the metal layer deposited in the first process cycle has an effective deposition thickness ranging from about 0.1 Ångström to about 1.5 Ångström.

9. The method of claim 1, wherein the oxidizing the deposited metal layer comprises supplying oxygen-containing gas on the metal layer at a flow rate of about 0.1 sccm to about 200 sccm at temperature of about 15° C. to about 50° C. for a supply time of about 0.5 seconds to about 10 seconds.

10. The method of claim 1, wherein performing the post-oxidation process comprises repeating the process cycle a predetermined number of times,
wherein oxidizing the deposited metal layer comprises supplying oxygen-containing gas on the metal layer in which a flow rate of the oxygen-containing gas increases as the process cycle is repeated.

11. The method of claim 1, wherein performing the post-oxidation process comprises repeating the process cycle a predetermined number of times,
wherein oxidizing the deposited metal layer comprises supplying oxygen-containing gas on the metal layer in which a supply time of the oxygen-containing gas increases as the process cycle is repeated.

12. The method of claim 1, wherein performing the post-oxidation process comprises repeating the process cycle a predetermined number of times,
wherein oxidizing the deposited metal layer comprises supplying oxygen-containing gas on the metal layer in which a flow rate and a supply time of the oxygen-containing gas increase as the process cycle is repeated.

13. The method of claim 1, wherein forming the tunnel insulating layer further comprises performing at least once a pre-oxidation process of depositing a metal oxide on an oxidized deposited metal layer.

14. The method of claim 13, wherein the pre-oxidation process is performed using an RF sputtering process in which at least one of tantalum oxide, magnesium oxide, ruthenium oxide, iridium oxide, platinum oxide, palladium oxide, titanium oxide, aluminum oxide, magnesium zinc oxide, hafnium oxide, or magnesium boron oxide is used as a sputtering target material.

15. The method of claim 13, wherein the metal oxide deposited during the pre-oxidation process comprises a thickness of about 3 Ångströms to about 10 Ångströms.

16. The method of claim 1, wherein the stabilizing process comprises annealing the tunnel insulating layer at a temperature of about 50° C. to about 200° C. for about 10 seconds to about 1000 seconds.

17-20. (canceled)

21. A method of forming an interface perpendicular magnetic anisotropic (IPMA) magnetic tunnel junction, the method comprising:
forming a tunnel insulating layer on a magnetic layer by performing a post-oxidation process at least one time, the post-oxidation process comprising depositing a metal layer and oxidizing the deposited metal layer,
wherein a first time the post-oxidation process is performed, a first metal layer is deposited on the magnetic layer, and subsequent times the post-oxidation process is performed, the metal layer is deposited on an oxidized metal layer.

22. The method of claim 21, further comprising low-temperature annealing the tunnel insulating layer.

23-27. (canceled)

28. The method of claim 21, wherein a process time of each post-oxidation process decreases with the number of repetition of the post-oxidation process.

29-38. (canceled)

39. The method of claim 21, wherein forming the tunnel insulating layer further comprises performing at least once a pre-oxidation process of depositing a metal oxide on an oxidized deposited metal layer.

40-42. (canceled)
